(19) United States
(12) Patent Application Publication
(10) Pub. No.: US 2007/0029623 A1
(43) Pub. Date: Feb. 8, 2007

(54) Dual-gate field effect transistor

(75) Inventors: Yongxun Liu, Ibaraki (JP); Meishoku Masahara, Ibaraki (JP); Kenichi Ishii, Ibaraki (JP); Toshihiro Sekigawa, Ibaraki (JP); Eiichi Suzuki, Ibaraki (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: National Inst of Adv Industrial Science and Tech, Tokyo (JP)

(21) Appl. No.: 10/580,433

(22) PCT Filed: Dec. 6, 2004
(86) PCT No.: PCT/JP04/18525

§ 371 Date: May 24, 2006

(30) Foreign Application Priority Data
Dec. 5, 2003 (JP) 2003-407935
Dec. 5, 2003 (JP) 2003-408254
Dec. 5, 2003 (JP) 2003-408112

(51) Int. Cl. H01L 29/76; H01L 21/336

(52) U.S. Cl. 257/401; 438/284; 257/E29.12; 257/E29.13

(57) ABSTRACT

A dual-gate field effect transistor includes a substrate 1, a source 7-1, a drain 7-2, a vertical channel 5 provided between the source and the drain as rising from the substrate, a pair of gate insulation films 6-1 and 6-2 sandwiching the channel from a direction orthogonal to a carrier-running direction in the channel and a pair of gate electrodes 3-1 and 3-2 facing the vertical channel 5, respectively, via the pair of gate insulation films 6-1 and 6-2, wherein the pair of insulation films have different thicknesses t1 and t2. It is also possible that the pair of gate insulation films 6-1 and 6-2 have different permittivities ε1 and ε2 and that the pair of gate electrodes have different work functions Φ1 and Φ2. Thus, it is possible to set the threshold voltage of the dual-gate field effect transistor to a desired value when fabricating it. Furthermore, it is possible to avoid the problem of an increase in subthreshold slope that occurs in the prior art.

### TECHNICAL FIELD

The present invention relates to an improvement in a so-called dual-gate field effect transistor having a carrier-running channel sandwiched via gate insulation films between a pair of gates from a direction orthogonal to the carrier-running direction, the gates being electrically connected to each other or being electrically independent of (insulatively separated from) each other.

### BACKGROUND ART

As is widely known, when miniaturization of individual Metal-Oxide Semiconductor (MOS) field effect transistors as the devices is facilitated for the purpose of realizing high integration and high speed thereof, a source and a drain come close to each other and, with this, a drain field has an affection on the source. As a result, a phenomenon that is generally called a short channel effect emerges and deteriorates the device performance. The deterioration includes, for example, reduction in threshold voltage, hebetation in rise of a drain current relative to a gate voltage increase in subthreshold slope) and accretion in leak current between the source and the drain.

When a so-called “dual-gate structure,” in which a thin channel region is sandwiched from the direction orthogonal to the carrier-running direction via gate insulation films between a pair of gates electrically connected to or electrically independent of each other, is adopted, the drain field can effectively be shielded to enable the short channel effect to be suppressed. It has recently been recognized that the structure of a dual-gate field effect transistor is most suitable for miniaturization of transistors, and various proposals have been made.

One of the conventional proposals is shown in FIGS. 27(A) to 27(C). A thin vertical channel 5 rising from the principal surface of the substrate is disposed on buried oxide films 2 formed on a substrate 1. When being seen in a Y-Y direction orthogonal to the carrier-running direction that is an X-X direction in FIG. 27(A), gate electrodes 3-1 and 3-2 face the opposite sides of the vertical channel 5, respectively, via gate insulation films 6-1 and 6-2. FIG. 27(C) is a cross-sectional end view taken along line X-X in FIG. 27(A), and FIG. 27(B) is a cross-sectional end view taken along line Y-Y orthogonal to line X-X.

In the case shown, since a pair of gate electrodes 3-1 and 3-2 disposed one by one outside the gate insulation films 6-1 and 6-2 are electrically connected to each other at a portion 3c bridging over an insulation film 4 formed on the vertical channel 5, they may be regarded as a single gate electrode from the standpoint of a device.

On the other hand, in the X-X direction that is the carrier-running direction, a source and a drain 7-1 and 7-2 are disposed across and connected to the vertical channel 5. While the adjective “vertical” is given to the channel 5 because the channel 5 has a rising relation relative to the substrate 1, it is omitted from the following description unless otherwise particularly required, and the vertical channel may also be simply called the channel.

In this dual-gate field effect transistor structure, since the gates 6-1 and 6-2 disposed on the opposite sides of the channel 5 come to electrically shield the channel, the affection of the drain field on the potential distribution in the interface between the source 7-1 and the channel region can be suppressed to enable prevention of an abrupt decrease in threshold voltage and an abrupt increase in subthreshold slope both accompanied by the realization of a short channel. However, the structure is disadvantage in that the generally used method by impurity control cannot effectively be used for the operation of controlling the threshold voltage indispensable to a Complementary Metal-Oxide Semiconductor (CMOS) circuit in the dual-gate field effect transistor exhibiting its features when being miniaturized by having such a thin channel. The miniaturized dual-gate field effect transistor having such an extremely thin channel layer poses an obstacle on the impurity fluctuation, resulting in a threshold voltage variation.

To solve the problem, another conventional proposal has been made, the structure of which is disclosed, for example, in Document 1: JP-A 2002-270850 and shown in FIGS. 28(A) to 28(C). Incidentally, it is described in advance that throughout the description and the accompanying drawings, the constituent elements given the same reference numerals indicate the same or corresponding constituent elements and that when the description of the constituent elements is applicable in line with other places of description and other drawings, there is a case where repetition of the same description of the constituent elements is avoided every one figure unless otherwise noted.

Though the conventional structure shown in FIG. 28 is fundamentally the same as that shown in FIG. 27, a different point is that a pair of gate electrodes 3-1 and 3-2 facing a channel 5, respectively, via a pair of gate insulation films 6-1 and 6-2 and having the periphery thereof surrounded by buried insulation films 8-1 and 8-2 are electrically isolated from each other (not connected to each other and in an insulatively separated state). For this, while one of the gate electrodes is kept applied with a fixed bias, the transistor can be driven by the bias voltage applied independently to the other gate electrode and, since a change in the value of the fixed bias can change the threshold voltage of the transistor, it becomes also possible to control the threshold voltage of the transistor.

There is still another conventional structure disclosed in publicly known document 2: “Analytical Models for n+-p+ Double-Gate SOI MOSFETs” K. Suzuki et al., IEEE ED, Vol. 42 No. 11, 1995, pp. 1940-1948” and shown in FIG. 29. In this structure, a channel 5 between a source and a drain 7-1 and 7-2 is made not vertical but lateral and sandwiched via a pair of gate insulation films 6-1 and 6-2 between a pair of mutually independent upper and lower gate electrode 3-1 and 3-2 extending in parallel to the principal surface of a substrate. This is an improvement in a so-called planar structure in which the upper gate electrode 3-1 is formed of n+ (or p+) polysilicon and the lower gate electrode 3-2 is formed of p+ (n+) polysilicon. That is to say, the upper and lower gate electrodes 3-1 and 3-2 are formed of polysilicons different in Fermi level to make the threshold voltage controllable.

However, the conventional structure shown in FIG. 27 cannot control the threshold voltage as described above. On the other hand, though the conventional structure shown in FIG. 28 can at least control the threshold voltage of the transistor, insufficient characteristic results can only be obtained and, in particular, the structure has a disadvantage in that the subthreshold slope is bumped up. In the conventional structure having a lateral channel shown in FIG. 29, though the threshold voltage of the transistor is made controllable, since the Fermi levels of the n+ or p+ polysilicon actually used are fixed values, it cannot be said that the threshold voltage is freely controlled. In addition, from the structural point of view, the structure is of a planar type extremely difficult to fabricate a self-aligned dual-gate.

The present invention has been accomplished in order to eliminate or alleviate the conventional disadvantages and with the object of providing a dual-gate field effect transistor having an arch-structure capable of controlling the threshold voltage freely above a certain level.

### DISCLOSURE OF THE INVENTION

To attain the above object, the present invention provides a dual-gate field effect transistor comprising a substrate, a source, a drain, a vertical channel provided between the source and the drain as rising from the substrate, a pair of gate insulation films sandwiching the channel from a direction orthogonal to a carrier-running direction in the channel and a pair of gate electrodes facing the channel, respectively, via the pair of gate insulation films, wherein the pair of insulation films have different thicknesses, thereby enabling the dual-gate field effect transistor to have a desirable threshold voltage within a range not giving rise to an increase in subthreshold slope.

In the above configuration, the present invention also provides a dual-gate field effect transistor, in which the pair of gate insulation films have different permittivities or different work functions in place of the different thicknesses. This is also means to obtain a desirable threshold voltage without being accompanied by the conventional disadvantages.

Furthermore, two or all means of the different thicknesses, different permittivities and different work functions of the pair of gate insulation films may arbitrarily be combined.

In the dual-gate field effect transistor according to the present invention, as described above, the pair of gate electrodes may be electrically connected to each other. Furthermore, it is preferable that they be made electrically independent of each other (insulatively separated from each other). With this, while the gate electrode facing the gate insulation film having a smaller thickness or a higher permittivity, for example, is used as a drive electrode, the gate electrode facing the other gate insulation film is given a suitable potential control. As a result, it becomes possible to electrically control the threshold voltage dynamically even under the device operation while preventing a steep increase in subthreshold slope.

Furthermore, in the case of the pair of gate electrodes having different work functions, it goes without saying that the threshold voltage can be controlled and, moreover, in the method of applying a fixed bias to the gate electrode having a low work function, the drain current can considerably be reduced depending on the applied bias voltage to abruptly shut off the drain current and, in the method of applying a fixed bias to the gate electrode having a high work function, the current-voltage characteristics can be shifted in parallel to make it possible to control the threshold voltage in a wide range.

The present invention also provides as another structural improvement a channel triangular in cross section as seen from the direction orthogonal to the carrier-running direction with a pair of gate insulation films in contact with slant faces that are the opposed sides of the triangle. This structure is effective for controlling the short channel effect more considerably The miniaturization of the channel alone can make the parasitic resistance of the source and drain small.

It is clear that use of a plurality of the dual-gate field effect transistors according to the present invention can develop an arbitrary semiconductor integrated circuit.

### BRIEF DESCRIPTION OF THE DRAWINGS

FIG. 1(A) is a plan view showing the configuration of a dual-gate field effect transistor according to a first preferred embodiment of the present invention.

FIG. 1(B) is a cross-sectional end view taken along line Y-Y in FIG. 1(A).

FIG. 1(C) is a cross-sectional end view taken along line X-X in FIG. 1(A).

FIG. 2(A) is a cross-sectional end view taken along the direction the same as line Y-Y in FIG. 1(A) at the initial step of a process for fabricating the dual-gate field effect transistor of the present invention shown in FIG. 1.

FIG. 2(B) is a cross-sectional end view as seen from the direction orthogonal to the direction in FIG. 2(A).

FIG. 3(A) is a cross-sectional end view taken along the same direction as in FIG. 2(A) at the next step of the process of FIG. 2.

FIG. 3(B) is a cross-sectional end view as seen from the direction orthogonal to the direction in FIG. 3(A).

FIG. 4(A) is a cross-sectional end view taken along the same direction as in FIG. 2(A) at the step subsequent to the step in FIG. 3.

FIG. 4(B) is a cross-sectional end view as seen from the direction orthogonal to the direction in FIG. 4(A).

FIG. 5(A) is a cross-sectional end view taken along the same direction as in FIG. 2(A) at the step subsequent to the step in FIG. 4.

FIG. 5(B) is a cross-sectional end view as seen from the direction orthogonal to the direction in FIG. 5(A).

FIG. 6(A) is a cross-sectional end view taken along the same direction as in FIG. 2(A) at the step subsequent to the step in FIG. 5.

FIG. 6(B) is a cross-sectional end view as seen from the direction orthogonal to the direction in FIG. 6(A).

FIG. 7(A) is a cross-sectional end view taken along the same direction as in FIG. 2(A) at the step subsequent to the step in FIG. 6.

FIG. 7(B) is a cross-sectional end view as seen from the direction orthogonal to the direction in FIG. 7(A).

FIG. 8(A) is a cross-sectional end view taken along the same direction as in FIG. 2(A) at the step subsequent to the step in FIG. 7.

FIG. 8(B) is a cross-sectional end view as seen from the direction orthogonal to the direction in FIG. 8(A).

FIG. 9(A) is a cross-sectional end view taken along the same direction as in FIG. 2(A) at the step subsequent to the step in FIG. 8.

FIG. 9(B) is a cross-sectional end view as seen from the direction orthogonal to the direction in FIG. 9(A).

FIG. 10(A) is a cross-sectional end view taken along the same direction as in FIG. 2(A) at the step subsequent to the step in FIG. 9.

FIG. 10(B) is a cross-sectional end view as seen from the direction orthogonal to the direction in FIG. 10(A).

FIG. 11(A) is a plan view showing the configuration of a dual-gate field effect transistor according to a second preferred embodiment of the present invention.

FIG. 11(B) is a cross-sectional end view taken along line Y-Y in FIG. 1(A).

FIG. 11(C) is a cross-sectional end view taken along line X-X in FIG. 1(A).

FIG. 12(A) is a cross-sectional end view taken along the direction the same as line Y-Y in FIG. 11(A) at the initial step of a process for fabricating the dual-gate field effect transistor of the present invention shown in FIG. 11.

FIG. 12(B) is a cross-sectional end view as seen from the direction orthogonal to the direction in FIG. 12(A).

FIG. 13(A) is a cross-sectional end view taken along the same direction as in FIG. 12(A) at the next step of the process of FIG. 12.

FIG. 13(B) is a cross-sectional end view as seen from the direction orthogonal to the direction in FIG. 13(A).

FIG. 14(A) is a cross-sectional end view taken along the same direction as in FIG. 12(A) at the step subsequent to the step in FIG. 13.

FIG. 14(B) is a cross-sectional end view as seen from the direction orthogonal to the direction in FIG. 14(A).

FIG. 15(A) is a cross-sectional end view taken along the same direction as in FIG. 12(A) at the step subsequent to the step in FIG. 14.

FIG. 15(B) is a cross-sectional end view as seen from the direction orthogonal to the direction in FIG. 15(A).

FIG. 16(A) is a cross-sectional end view taken along the same direction as in FIG. 12(A) at the step subsequent to the step in FIG. 15.

FIG. 16(B) is a cross-sectional end view as seen from the direction orthogonal to the direction in FIG. 16(A).

FIG. 17(A) is a cross-sectional end view taken along the same direction as in FIG. 12(A) at the step subsequent to the step in FIG. 17.

FIG. 17(B) is a cross-sectional end view as seen from the direction orthogonal to the direction in FIG. 17(A).

FIG. 18(A) is a cross-sectional end view taken along the same direction as in FIG. 12(A) at the step subsequent to the step in FIG. 17.

FIG. 18(B) is a cross-sectional end view as seen from the direction orthogonal to the direction in FIG. 18(A).

FIG. 19(A) is a cross-sectional end view taken along the same direction as in FIG. 12(A) at the step subsequent to the step in FIG. 19.

FIG. 19(B) is a cross-sectional end view as seen from the direction orthogonal to the direction in FIG. 19(A).

FIG. 20(A) is a cross-sectional end view taken along the same direction as in FIG. 12(A) at the step subsequent to the step in FIG. 19.

FIG. 20(B) is a cross-sectional end view as seen from the direction orthogonal to the direction in FIG. 20(A).

FIG. 21(A) is a cross-sectional end view taken along the same direction as in FIG. 12(A) and showing a dual-gate field effect transistor according to a third preferred embodiment of the present invention.

FIG. 21(B) is a cross-sectional end view as seen from the direction orthogonal to the direction in FIG. 21(A).

FIG. 22(A) is a cross-sectional end view taken along the same direction as in FIG. 12(A) and showing a dual-gate field effect transistor according to a fourth preferred embodiment of the present invention.

FIG. 22(B) is a cross-sectional end view as seen from the direction orthogonal to the direction in FIG. 22(A).

FIG. 23 is a diagram showing the dependency of the subthreshold slope (right vertical axis: mV/dec.) and the threshold voltage (left vertical axis: V) on the gate voltage (lateral axis: Vgc) in the first preferred embodiment when the thickness t1 of one of the pair of gate insulation films is fixed to 2 nm, with the thickness t2 of the other gate insulation film varied from 2 nm to 20 nm.

FIG. 24 is a characteristic diagram showing the relationship between the subthreshold slope (left vertical axis: mV/dec.) and the threshold voltage (lateral axis: V) under the same conditions as in FIG. 23.

FIG. 25(A) is a plan view showing the configuration of a dual-gate field effect transistor according to a fifth preferred embodiment of the present invention.

FIG. 25(B) is a cross-sectional end view taken along line Y-Y in FIG. 25(A).

FIG. 25(C) is a cross-sectional end view taken along line X-X in FIG. 25(A).

FIG. 26(A) is a plan view showing the configuration of a dual-gate field effect transistor according to a sixth preferred embodiment of the present invention.

FIG. 26(B) is a cross-sectional end view taken along line Y-Y in FIG. 26(A).

FIG. 26(C) is a cross-sectional end view taken along line X-X in FIG. 26(A).

FIG. 27(A) is a plan view showing the configuration of a conventional dual-gate field effect transistor.

FIG. 27(B) is a cross-sectional end view taken along line Y-Y in FIG. 27(A).

FIG. 27(C) is a cross-sectional end view taken along line X-X in FIG. 27(A).

FIG. 28(A) is a plan view showing the configuration of another conventional dual-gate field effect transistor.

FIG. 28(B) is a cross-sectional end view taken along line Y-Y in FIG. 28(A).

FIG. 28(C) is a cross-sectional end view taken along line X-X in FIG. 28(A).

FIG. 29 is a cross-sectional end view showing still another conventional dual-gate field effect transistor.

### BEST MODE FOR CARRYING OUT THE INVENTION

The present invention will be described in more detail with reference to the accompanying drawings.

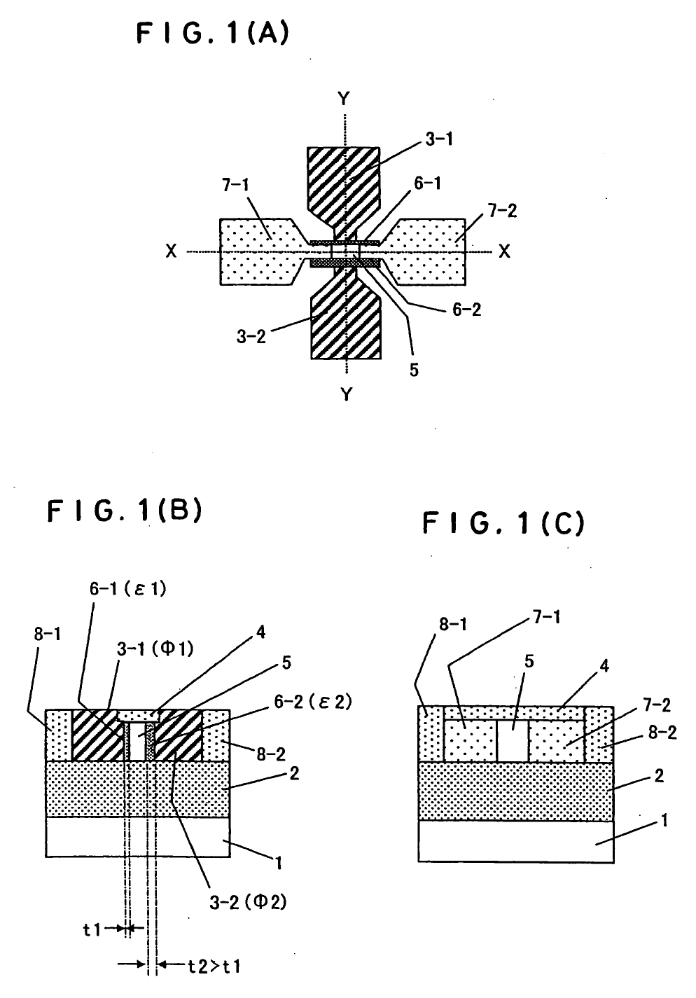

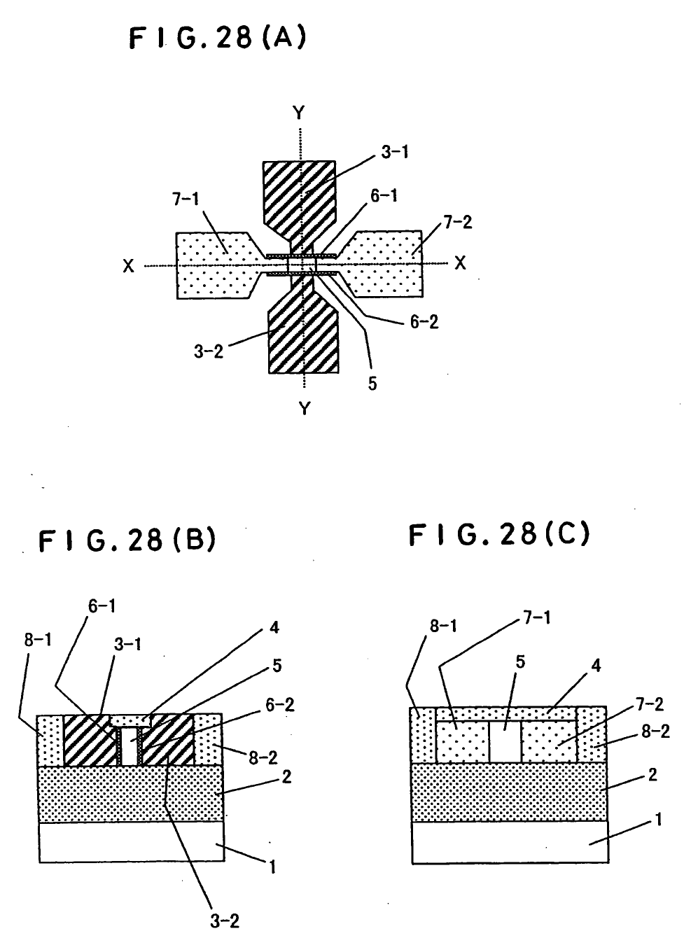

FIGS. 1(A) to 1(C) schematically show the configuration of a dual-gate field effect transistor according to the first embodiment of the present invention. FIG. 1(B) is a cross-sectional end view taken along line Y-Y in FIG. 1(A), and FIG. 1(C) is a cross-sectional end view taken along line X-X in FIG. 1(A). The positional relationship of a channel 5, a source 7-1, a drain 7-2, a pair of gate insulation films 6-1 and 6-2 and a pair of gate electrodes 3-1 and 3-2 relative to a substrate 1 may be the same as that of the conventional structure described earlier with reference to FIG. 28. That is to say, the vertical channel 5 formed between the source 7-1 and the drain 7-2 to have a rising relation relative to the substrate 1 is sandwiched in the direction orthogonal to the carrier-running direction in the vertical channel between a pair of gate insulation films 6-1 and 6-2 on which the gate electrodes 3-1 and 3-2, respectively, that are also paired. Though not Imitative, the constituent elements starting with the channel 5 are formed on the buried insulation film 2 in the case shown in the drawings, and the upper part of the channel 5 is covered with the insulation film 4.

The characteristic feature of the present invention lies in that the thicknesses t1 and t2 of the paired gate insulation films 6-1 and 6-2 differ from each other unlike in the conventional structure shown in FIG. 28. The case of the thickness t2 of one 6-2 of the gate insulation film on the left side being larger than the thickness t1 of the other gate insulation film 6-1 on the right side in the drawing (t1<t2) is exemplified.

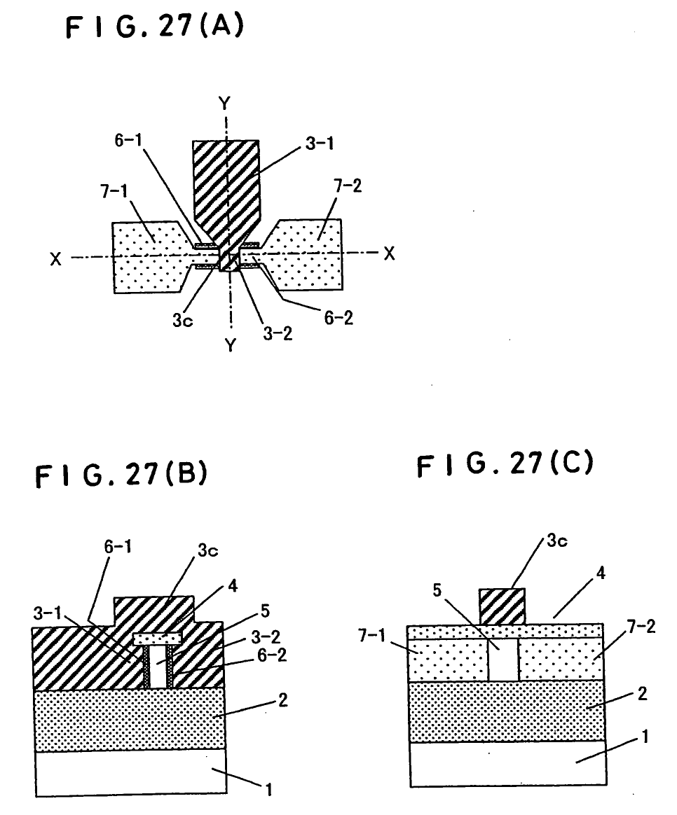

In this structure, the disadvantages of the prior art described with reference to FIGS. 27 and 28 are eliminated or alleviated and, through adjustment of the thicknesses t1 and t2 of the gate insulation films 6-1 and 6-2 during the device fabrication processes, a desirable threshold voltage can be obtained within a range not giving rise to an increase in subthreshold slope. Furthermore, when the paired gate electrodes 3-1 and 3-2 are electrically independent of each other, as shown in the drawings, while using the gate electrode 3-1 facing the thinner gate insulation film 6-1 as a drive electrode, for example, by applying an appropriate control bias voltage to the gate electrode 3-2 facing the thicker gate insulation film 6-2, the threshold voltage of the field effect transistor can electrically controlled dynamically even during the device operation thereof, with a steep increase of the subthreshold slope thereof prevented.

In addition, in accordance with a specific manner of the present invention, the permittivities ε1 and ε2 of the paired gate insulation films 6-1 and 6-2 may be made different from each other (i.e. ε1≠ε2). By the adjustment of the permittivities ε1 and ε2 of the paired gate insulation films 6-1 and 6-2 in addition to the adjustment of the insulation film thicknesses, a desirable threshold voltage can be obtained with fine adjustment within a range not giving rise to an increase in subthreshold slope. The materials for the gate insulation films 6-1 and 6-2 having respectively independent permittivities ε1 and ε2 can be selected appropriately from the existing materials with a considerable extent of the degree of freedom and, by adopting a multilayer structure as obtained in the step described later, an effective permittivity thereof can also be determined to a desirable value. These points can also be applicable to any of the embodiments described later.

Besides the adjustment of the thicknesses of the insulation films or the adjustment of both the thicknesses and the permittivities of the insulation films, in accordance with another specific manner of the present invention, the work function Φ1 of one of the gate electrodes 3-1 and the work function Φ2 may be made different from each other (i.e. Φ1≠Φ2). By this adjustment of the work functions Φ1 and Φ2 given to the paired gate electrodes 3-1 and 3-2 during the production, the desirable threshold voltage of the device can also be obtained within a range not giving rise to an increase in subthreshold slope. The materials for the gate electrodes 3-1 and 3-2 having the relation of the work functions can also be selected appropriately from the existing materials with a considerable extent of the degree of freedom and, as in the step described later, the configuration using an appropriate ion implantation technique can also be used. These points can also be applicable to any of the embodiments of the present invention described later.

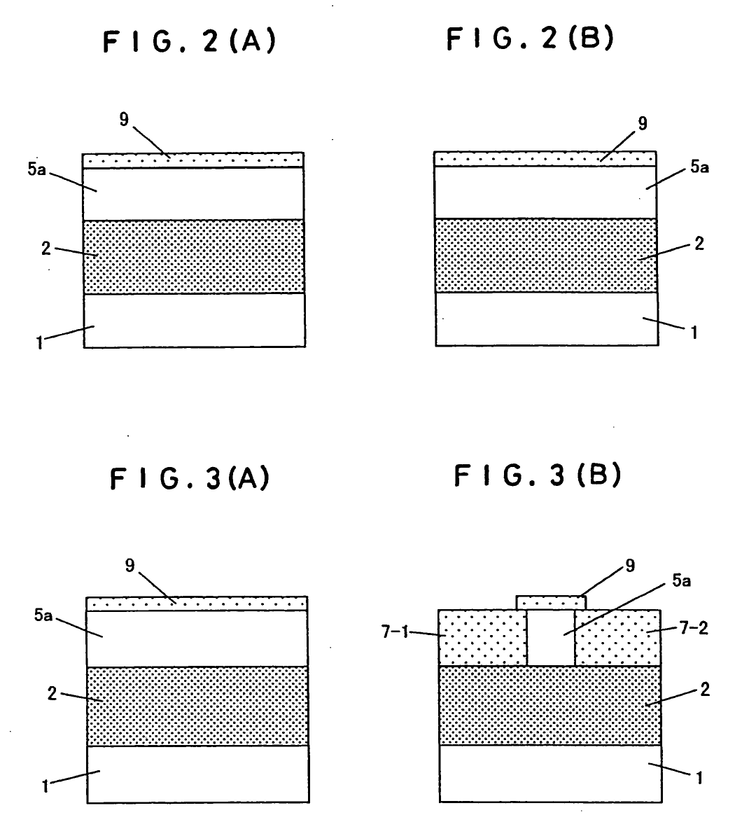

A process for fabricating the dual-gate field effect transistor of the present invention shown in FIG. 1 will be descried with reference to FIGS. 2 to 10. Incidentally, here and in other embodiments, it is assumed that the vertical channel 5 is an n-type channel. However, even a p-type channel can also be similarly applied to each step described hereinafter. In FIGS. 2 to 10, each figure given (A) corresponds to a cross-sectional end view along line Y-Y in FIG. 1, and each figure given (B) to a cross-sectional end view along line X-X in FIG. 1. Therefore, the figures given (A) and the figures give (B) are cross-sectional end views seen from the directions orthogonal to each other.

As shown in FIGS. 2(A) and 2(B), an SOI (Silicon-On-Insulator) wafer having on a silicon substrate 1, a buried oxide film 2 and a silicon crystal layer 5a is prepared, and the surface thereof is thermally oxidized to form a silicon dioxide film. Thereafter, as shown in FIGS. 3(A) and 3(B), the silicon dioxide film is patterned into a desired pattern by the electron beam lithography and Reactive Ion Etching (RIE), for example, a doping mask 9 is produced, and a heavily doped source region 7-1 and a drain region 7-2 are formed by doping.

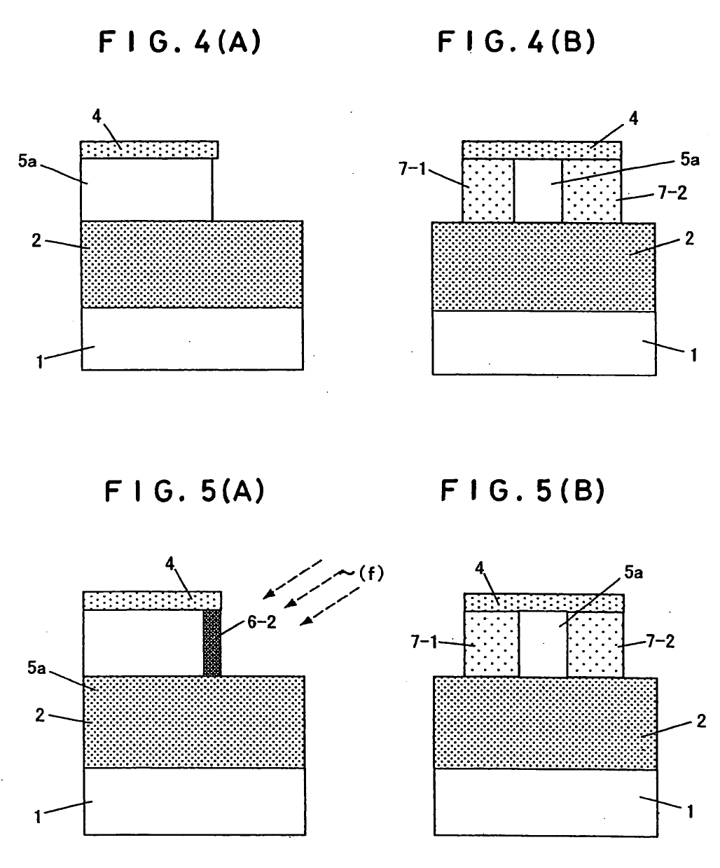

As shown in FIGS. 4(A) and 4(B), after removing the doping mask by a hydrofluoric acid, an oxide film and a nitride film are then continuously deposited to form an insulation film 4, patterning is performed by the electron beam lithography, and a hard mask composed of an insulation film 4 is formed by the RIE. A silicon wall vertical to the substrate 1 is then formed on the right side of the channel 5 by the crystal anisotropic wet-etching or RIE. At this time, each of the source region 7-1 and drain region 7-2 is simultaneously shaped on one side thereof. With this state maintained, as shown in FIGS. 5(A) and 5(B), a gate insulation film 6-2 that will finally be a relatively thick gate insulation film is formed by the thermal oxidation or Chemical Vapor Deposition (CVD). In this process, though a silicon dioxide film is actually formed on each side of the source and drain 7-1 and 7-2, it is not shown in the drawings.

When changing the permittivities ε1 and ε2 of the pair of gate insulation films as already shown in FIG. 1(B) in addition to the thicknesses thereof in accordance with a specific manner of the present invention, an insulation thin film of an appropriate insulation material different from that of the silicon thermal oxidation film is formed in an stacked form in the step of FIG. 5 by the known and existing tilted deposition technique as shown by virtual arrows f in FIG. 5(A) or sputtering method. As the material for the film overlapped, insulation materials, such as HfSiON, HfAlSiON and La₂O₃ can be adopted. However, the step of actually changing the permittivity of the gate insulation film 6-2 is not taken here, but may be taken in a step described later with reference to FIG. 7. A specific insulation material having a desirable thickness may, of course, be deposited initially without performing the thermal oxidation.

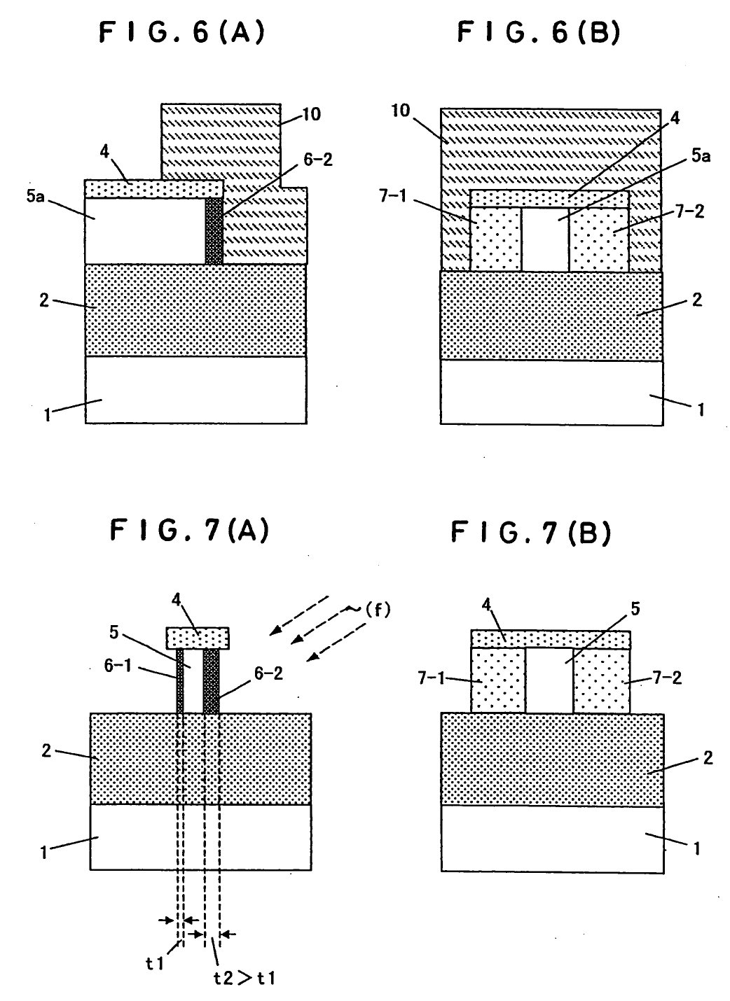

As shown in FIGS. 6(A) and 6(B), a resist pattern 10 is formed by the electron beam lithography, for example. What is important here is that the resist pattern 10 covers the thick gate oxide film 6-2 already formed and extends leftward by the channel thickness (a thickness toward the pair of gate electrodes). For this, though alignment with nanoscale precision is required in this process, this problem can satisfactorily be solved with the existing technique. After the formation of the resist pattern 10, a hard mask composed of an insulation film 4 is formed, the silicon layer is etched by the crystal anisotropic wet-etching or RIE to form a vertical silicon wall on the left side of the channel 5, and a thin gate oxide film is formed by a short-time thermal oxidation, as shown in FIGS. 7(A) and 7(B). In this step, as described earlier with reference to FIG. 5(A), the permittivity-changing step of depositing an aforementioned appropriate material as shown by virtual arrows f may be taken relative to either one of the gate insulation films, i.e. the thick gate insulation film 6-2, for example. Where the permittivity-changing step is taken similarly in this step relative to the thinner gate insulation film 6-1, an appropriate dielectric material is deposited in the opposite direction obliquely across the channel.

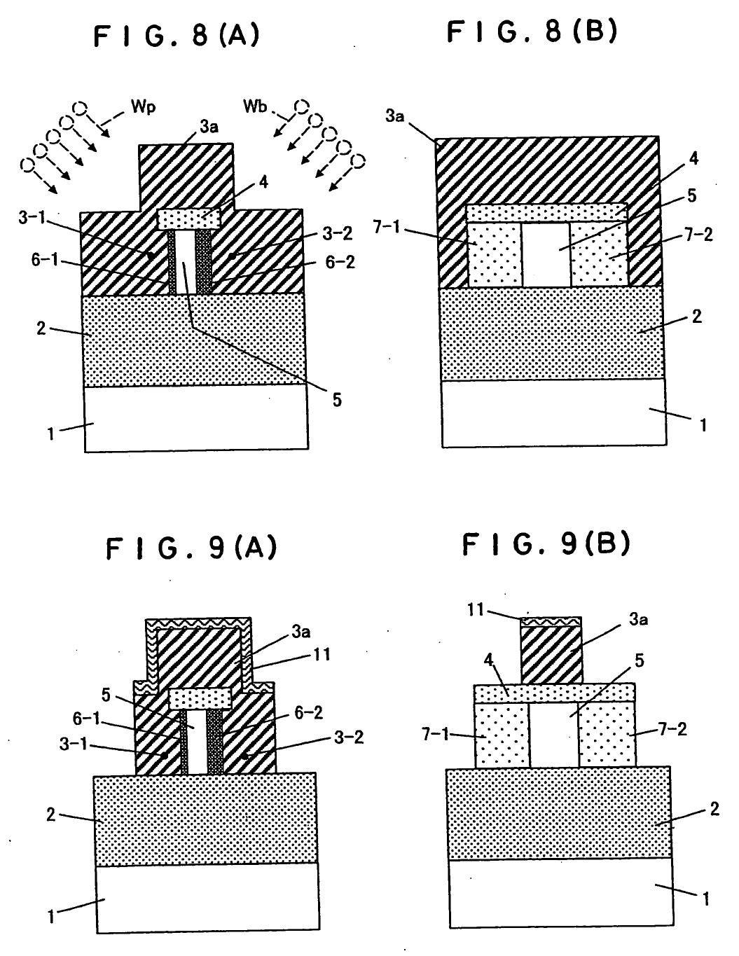

After the formation of the gate oxide film 6-1 of a relatively small thickness on the left side of the channel 5 and the gate oxide film 6-2 of a relatively large thickness on the right side thereof in the illustrated case, as described above, an electrode material 3a constituting a gate electrode is deposited over the entire surface of the wafer as shown in FIGS. 8(A) and 8(B). As appropriate electrode materials, doped polysilicon and a composite film formed of a thin metal film of a high melting point and polysilicon continuously deposited can be adopted.

Here, however, where the work functions of the pair of gate electrodes 3-1 and 3-2 are made different from each other in accordance with a specific manner of the present invention, the following step can be adopted.

Polysilicon, for example, is selected as the electrode material 3a and the polysilicon 3a is deposited. When phosphorus, for example, is implanted as shown in virtual arrows Wp in FIG. 8(A) by the tited ion implantation method, the phosphorus is implanted in a portion of the gate electrode 3-1 in contact with the thin gate insulation film 6-1 and in a portion of the gate electrode bridging over the insulation film 4. However, a portion of the gate electrode 3-2 in the vicinity of a portion of the gate electrode in contact with the thick gate insulation film 6-2 is shaded in the tilted ion implantation and, therefore, it remains without being implanted with the phosphorus. Next, when boron, for example, is implanted in the opposite direction obliquely across the channel 5 by the tilted ion implantation method as shown by virtual arrows Wb, the boron is implanted in a portion of the gate electrode 3-2 in contact with the thick gate insulation film 6-2 and in a portion of the gate electrode bridging over the insulation film 4 while the portion of the gate electrode 3-1 in contact with the thin insulation film 6-1 is not implanted with the boron and remains implanted with the phosphorus. The order of implantation may be reversed. At any rate, this step enables a pair of gate electrodes 3-1 and 3-2 having different work functions to be obtained in advance. Incidentally, in this embodiment, the work function of the gate electrode 3-1 in contact with the thin gate insulation film 6-1 and implanted with the phosphorus is lower than that of other gate electrode 3-2 implanted with the boron.

In either the case of providing the gate electrodes 3-1 and 3-2 with a difference in work function or the case of providing them with no difference, in order to make planar regions of the gate electrodes determinate finally after the step shown in FIG. 8, as shown in FIGS. 9(A) and 9(B), silicade glass 11 is deposited by the low-pressure CVD, a gate pattern is formed by the electron beam lithography, and a hard mask composed of silicade mask 11 is formed by RIE. Utilizing the hard mask, the gate material 3a is vertically etched to the buried oxide film 2 by RIE.

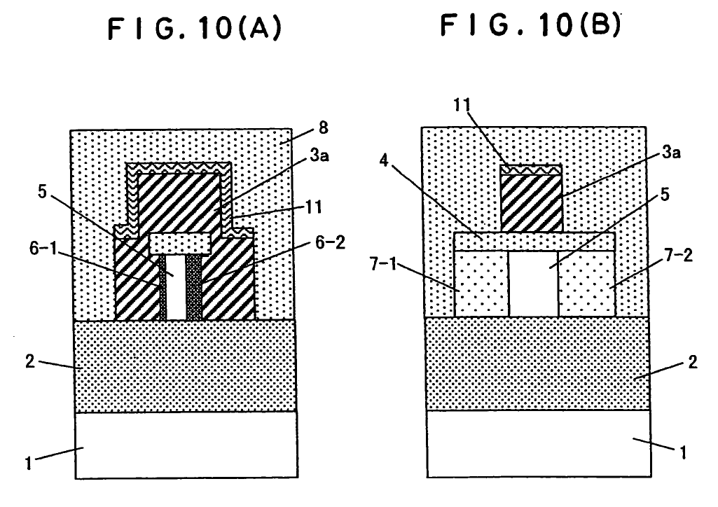

After completion of the fabrication of the structure described above, a Phosphorus-doped Silicade Glass (PSG) for an n-type channel, a Boron-doped Silicade Glass (BSG) for a p-type channel and a Non-doped Silicade Glass (NSG) for both types of channels are continuously deposited to form an insulation film 8 as shown in FIGS. 10(A) and 10(B). Then a Rapid Thermal Annealing (RTA) is performed for diffusing impurities into the source-drain extension regions at the opposite ends of the channel are doped. The insulation film is polished, with the insulation film 4 as a stopper, by the Chemical Mechanical Polishing (CMP), and the electrode material 3a is separated into a left gate electrode 3-1 and a right gate electrode 3-2 to obtain the dual-gate field effect transistor according to the specific manner of the present invention shown in FIG. 1.

Though not to be shown here, a device structure actually utilizable as a product can, of course, be obtained by depositing an insulation film over the entire surface of a wafer, forming contact holes, forming Al electrodes, and sintering the resultant. Since this can be achieved through inter connect wiring formation and packaging treatment taken for being granted in this kind of field, a further detailed description will be omitted. Based on the present invention, those skilled in the art are extremely easy to fabricate a semiconductor integrated circuit having an arbitrary function using a plurality of the dual-gate field effect transistors of the present invention. This point is applicable to any of the embodiments described below.

The ion implantation has been described above to make the work functions Φ1 and Φ2 of the pair of gate electrodes 3-1 and 3-2 different from each other. In the case of using different metal materials as another measure, one of the gate electrodes is made from the first electrode material in the steps shown in FIGS. 8 and 9 and the other gate electrode is made from the second electrode material of different material and different work function from those of the first electrode material in the same manner. The different materials suitable for combination are molybdenum and aluminum, for example.

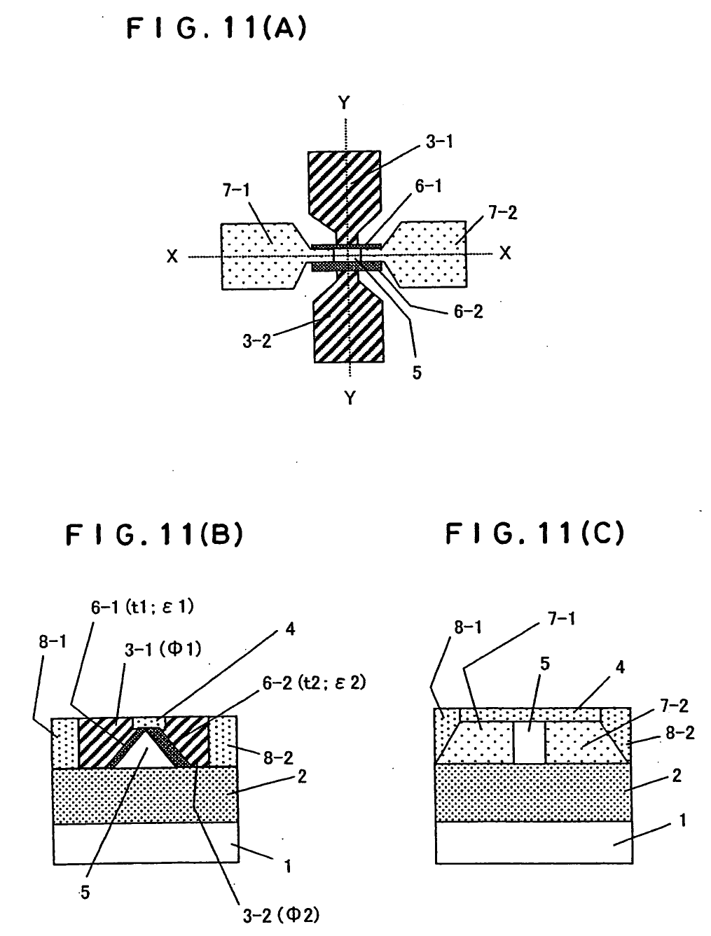

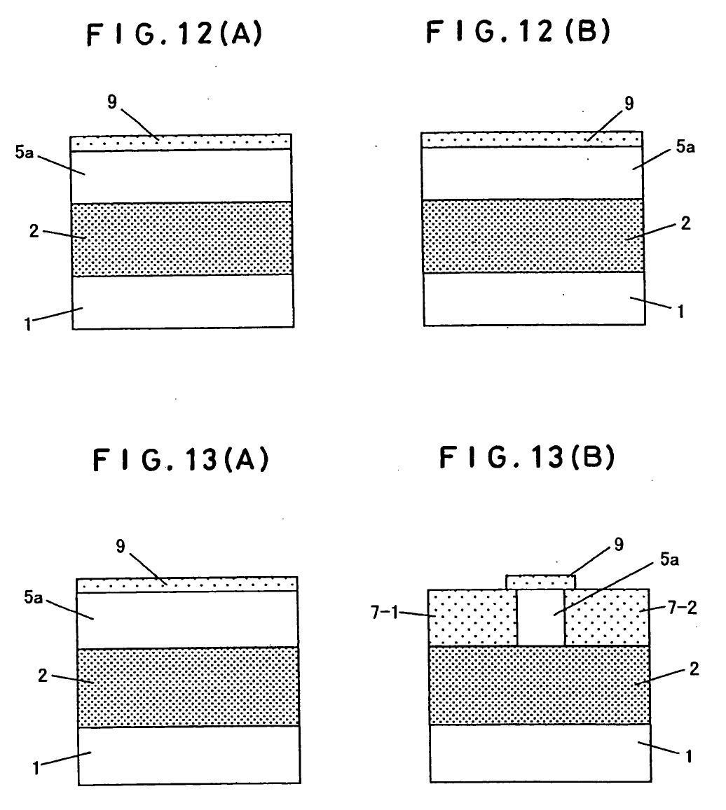

FIGS. 11(A) to 11(C) show a dual-gate field effect transistor according to another embodiment of the present invention. The different point from the field effect transistor of the present invention shown in FIG. 1 is that, as best shown in FIG. 11(B) that is a cross-sectional end view taken along line Y-Y in FIG. 11(A), the cross section of a channel in the direction connecting the gate electrodes 3-1 and 3-2, i.e. the direction orthogonal to the carrier-running direction (the cross section along line Y-Y) is triangular. This structure can be obtained through the use of an SOI substrate having (100) plane orientation and application of the crystal anisotropic wet etching. An example of the production process will be described herein below. In FIGS. 12 to 20, the figures given (A) correspond to cross-sectional end views taken along line Y-Y in FIG. 11, and the figures given (B) to cross-sectional end views taken along line X-X.

As shown in FIGS. 12(A) and 12(B), an SOI wafer having a silicon substrate provided with a buried oxide film 2 and a silicon crystal layer 5a is prepared. The surface thereof is thermally oxidized to form a silicon dioxide film and, as shown in FIGS. 13(A) and 13(B), a doping mask formed on the silicon dioxide film is prepared. Then, regions where a source 7-1 and a drain 7-2 are to be formed are doped with appropriate impurities.

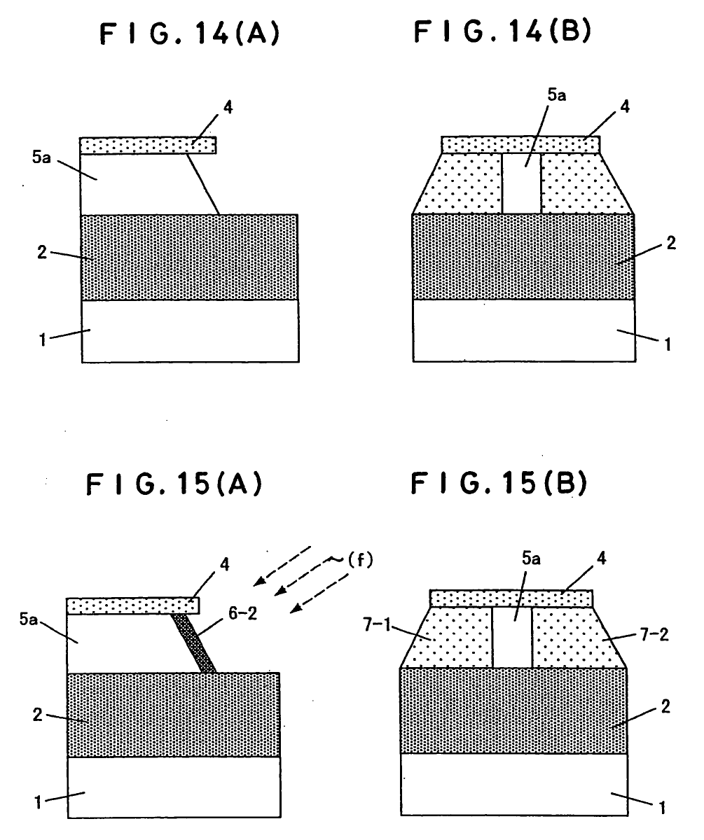

Then, as shown in FIGS. 14(A) and 14(B), a hard mask formed of the insulation film 4 is produced by RIE, and the silicon layer is etched with an aqueous 2.38% TetraMethyl Ammonium Hydroxide (TMAH) solution, thereby forming on the right side of the channel an exposed oblique silicon surface having (111) plane orientation. Then, a thermal oxidation or a CVD is performed for thereby forming a relatively thick gate insulation film 6-2 as shown in FIGS. 15(A) and 15(B). When changing the permittivities of the pair of gate insulation films as well as the thicknesses thereof in accordance with a specific manner also in the embodiment of the present invention, an insulation thin film of an appropriate insulation material different from that of the silicon thermal oxidation film is formed in a stacked form in this step by the known and existing tilted deposition technique as shown by virtual arrows f in FIG. 15(A) or sputtering method. As a result, the gate insulation film 6-2 different in permittivity from other gate insulation film 6-1 to be produced later can be obtained. As the material for the film stacked, insulation materials, such as HfSiON, HfAlSiON and La₂O₃ can be adopted. However, the step of actually changing the permittivity of the gate insulation film 6-2 is not taken here, but may be taken in a step described later with reference to FIG. 17. A specific insulation material having a desirable thickness may, of course, be deposited initially without performing the thermal oxidation.

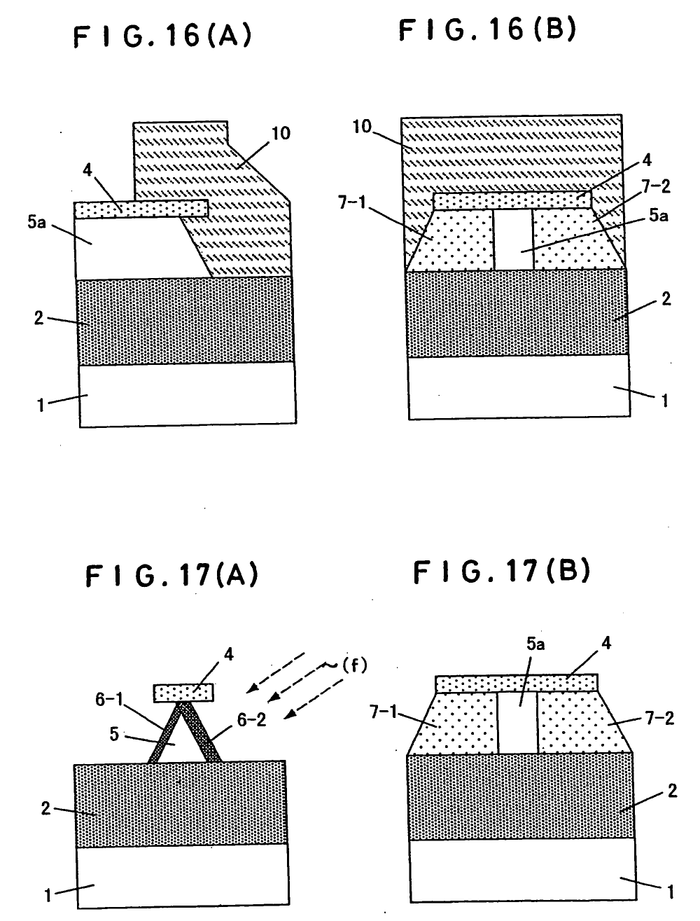

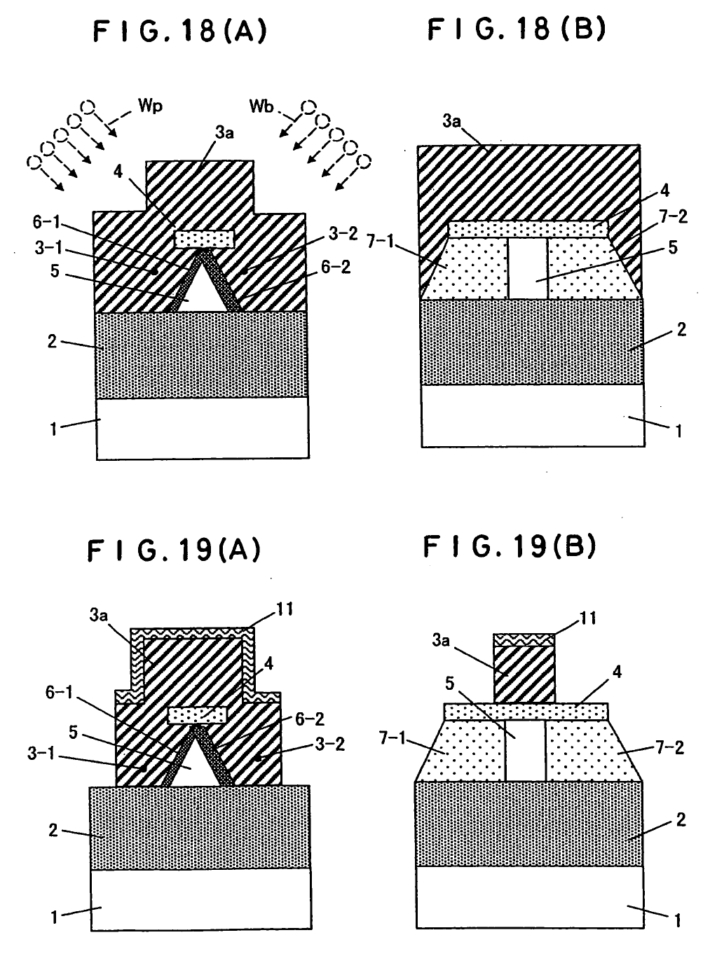

On the structure thus formed a resist pattern 10 is formed by electron beam lithography as shown in FIGS. 16(A) and 16(B) and, as shown in FIGS. 17(A) and 17(B), a hard mask composed of an insulation film 4 is formed by RIE, for example. Crystal anisotropic wet etching is used to form an oblique silicon surface having a (111) plane orientation, which is subjected to a short-time thermal oxidation to form a thin gate oxide film 6-2. As described earlier, when the permittivities of the pair of gate insulation films 6-1 and 6-2 are to be changed, in the step shown in FIG. 17, a permittivity-changing step by depositing an aforementioned appropriate material may be taken as shown by virtual arrows f relative to either one of the gate insulation films, i.e. the thick gate insulation film 6-2, for example, without taking the step shown in FIG. 15 shown by virtual arrows f shown in FIG. 15. Where the permittivity-changing step is taken similarly in this step relative to the thinner gate insulation film 6-1, an appropriate dielectric material is deposited in the opposite direction obliquely across the channel Thereafter, as shown in FIGS. 18(A) and 18(B), an electrode material 3a is deposited on the entire surface of the after and, as shown in FIGS. 19(A) and 19(B) and in accordance with the method described earlier, silicade glass 11 is deposited on the electrode material, a gate pattern is formed by the electron beam lithography, and a gate is fabricated by RIE.

In the case of making the work functions Φ1 and Φ2 of the pair of gate electrodes 3-1 and 3-2 different from each other in accordance with a specific manner of the present invention before the step shown in FIG. 19, in the step shown in FIG. 18, plysilicon, for example, is selected as the electrode material 3a and the polysilicon 3a is deposited. When phosphorus, for example, is implanted as shown in virtual arrows Wb in FIG. 18(A) by the tilted ion implantation method, the phosphorus is implanted in a portion of the gate electrode 3-1 in contact with the thin gate insulation film 6-1 and in a portion of the gate electrode bridging over the insulation film 4. However, a portion of the gate electrode 3-2 in the vicinity of a portion of the gate electrode in contact with the thick gate insulation film 6-2 forms a canopy of death of the oblique ion implantation to remain without being implanted with the phosphorus. Next, when boron, for example, is implanted in the opposite direction obliquely across the channel 5 by the oblique ion implantation method as shown by virtual arrows Wp, the boron is implanted in a portion of the gate electrode 3-2 in contact with the thick gate insulation film 6-2 and in a portion of the gate electrode bridging over the insulation film 4 while the portion of the gate electrode 3-1 in contact with the thin insulation film 6-1 is not implanted with the boron and remains implanted with the phosphorus. The order of implantation may be reversed. At any rate, this step enables a pair of gate electrodes 3-1 and 3-2 having different work functions to be obtained in advance. Incidentally, in this embodiment, the work function of the gate electrode 3-1 in contact with the thin gate insulation film 6-1 and implanted with the phosphorus is lower than that of other gate electrode 3-2 implanted with the boron.

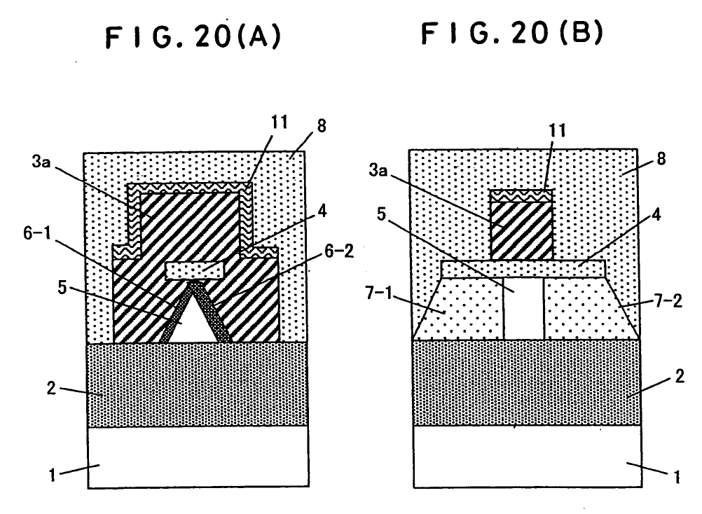

After the step shown in FIG. 19, as shown in FIGS. 20(A) and 20(B), PSG (BSG in the case of a p-type channel) and NSG are continuously deposited to form an insulation film 8. The insulation film is subjected to rapid thermal annealing and the impurities are diffused into the source-drain extension regions to form doped channel extensions. The resultant is polished utilizing Chemical Mechanical Polishing (CMP), with the insulation film 4 used as a stopper to thereby complete a dual-gate field effect transistor having separated gate electrodes 3-1 and 3-2 according to the present invention as shown in FIG. 11. As the subsequent treatments, the aforementioned treatments generally used in this kind of field are taken to complete a device as a product. In the case of using different metal materials to make the work functions of the pair of gate electrodes 3-1 and 3-2 different without the ion implantation, one of the gate electrodes is made from the first electrode material in the steps shown in FIGS. 18 and 19 and the other gate electrode is made from the second electrode material of different material and different work function from those of the first electrode material in the same manner. As the electrode materials to be combined, appropriate metal materials as described earlier may be selected.

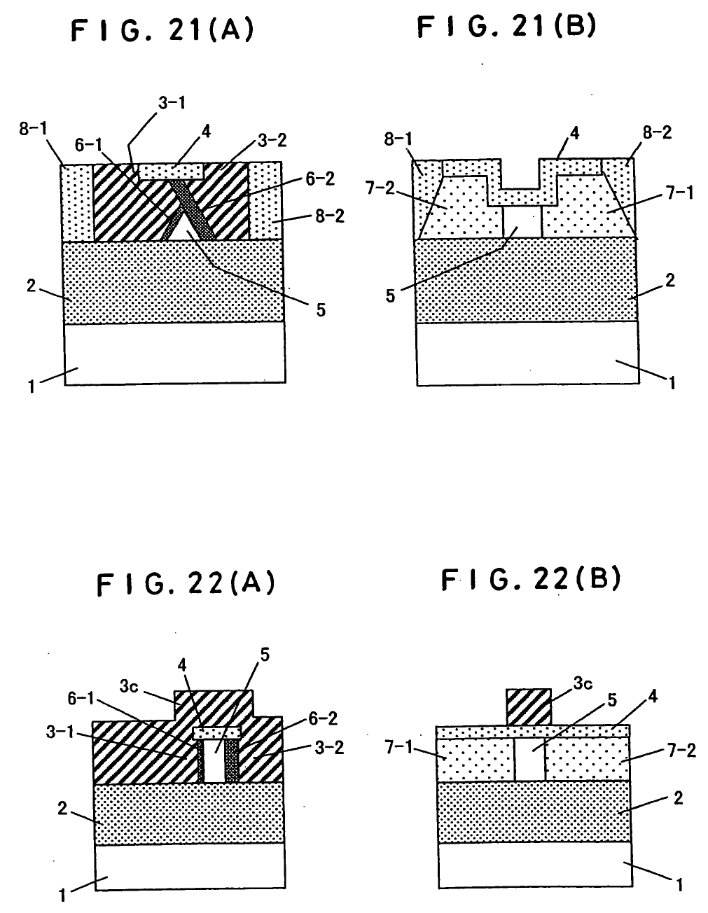

FIGS. 21(A) and 21(B) show another embodiment for forming a triangular channel 5. To be specific, a thin insulation film 6-1 collides against a portion midway through a thick insulation film 6-2 to form a triangular shape. Therefore, the triangular channel 5 is further miniaturized. Since making a vertical channel 5 triangular is effective for controlling the short channel effect conspicuously. By miniaturizing the triangular channel 5 in this way, the effect becomes greater. Also in this case, since the channel is only miniaturized, it is possible to make the parasitic resistance of the source and drain small (the extended source and drain remaining thick).

The fabrication process of this structure may be the same as the process described with reference to FIGS. 12 to 20. The point to be made different is the time of the crystal anisotropic wet etching in the step shown in FIGS. 17(A) and 17(B). The time is to be prolonged. The significant point is to accurately control the etching time.

FIGS. 22(A) and 22(B) show still another embodiment of the present invention and, in a certain sense, a fundamental embodiment. In the preceding embodiments, the pair of gate electrodes 3-1 and 3-2 are electrically independent of each other (insulatively separated). In this embodiment, the structure and the disposition relationship among the regions are the same as the conventional ones shown in FIG. 27, and the pair of gate electrodes 3-1 and 3-2 are connected to each other at a connection part 3c. Therefore, it is impossible to apply different potentials to the pair of gate electrodes 3-1 and 3-2. In accordance with the present invention, however, by adjusting the thicknesses t1 and t2 of the pair of gate insulation films 6-1 and 6-2 during the device fabrication processes and, in addition thereto, or in place thereof, in accordance with a specific manner of the present invention, by adjusting the relation between the permittivities ε1 and ε2 of the pair of gate insulation films 6-1 and 6-2 or the work functions Φ1 and Φ2 of the pair of gate electrodes 3-1 and 3-2 or by adjusting both the relation between the permittivities ε1 and ε2 of the pair of gate insulation films 6-1 and 6-2 and the work functions Φ1 and Φ2 of the pair of gate electrodes 3-1 and 3-2, it is made possible to obtain a degree of freedom capable of giving a desirable threshold voltage.

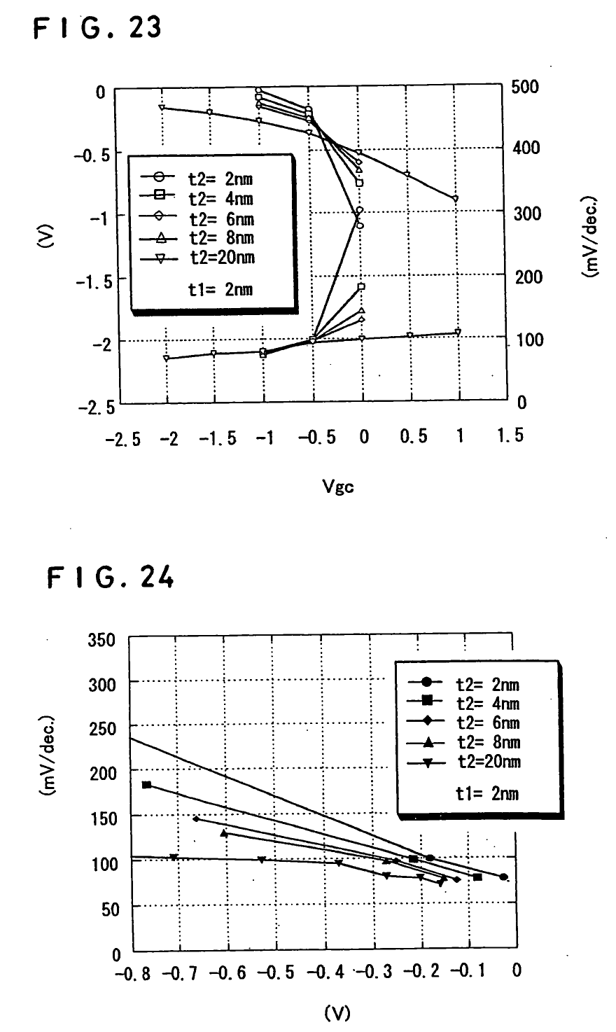

FIG. 23 shows the results of calculations in the embodiment described with reference to FIGS. 1 to 10, with the thickness t1 of the gate insulation film 6-1 fixed to 2 nm and the thickness t2 of the gate insulation film 6-2 varied from 2 nm to 20 nm. This shows the dependency of the subthreshold slope (right vertical axis: mV/dec.) and the threshold voltage (left vertical axis: V) on the gate voltage (lateral axis: Vgc) varying with a change in thickness of the gate insulation film t2, from which it is found that a transistor can be fabricated in accordance with the gist of the present invention while satisfactorily controlling the threshold voltage to a desired value. FIG. 24 shows an example of the features showing the relationship between the subthreshold slope (right vertical axis: mV/dec.) and the threshold voltage (lateral axis: V).

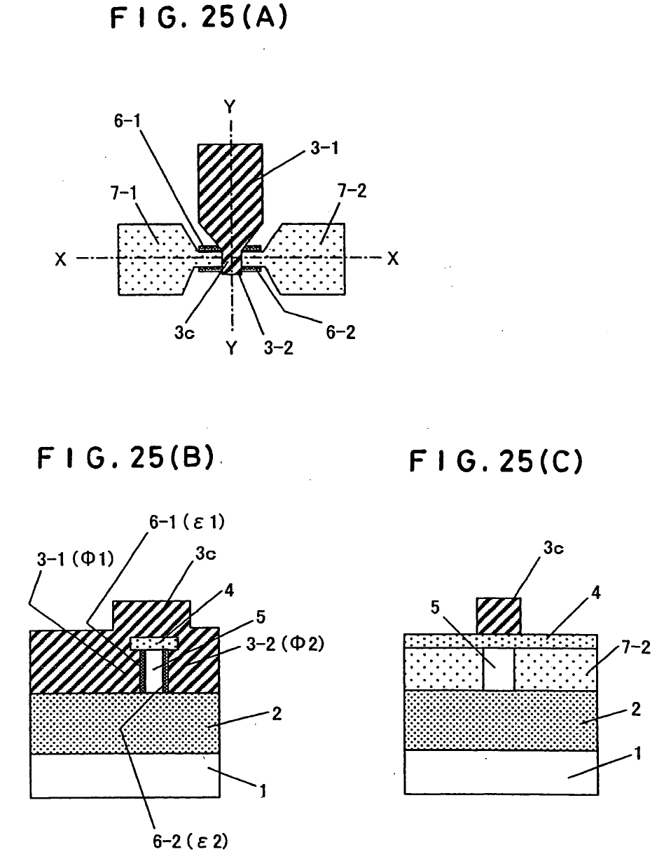

FIGS. 25(A) to 25(C) schematically show the configuration of the dual-gate field effect transistor according to yet another embodiment of the present invention. FIG. 25(B) is a cross-sectional end view taken along line Y-Y in FIG. 25(A) and FIG. 25(C) is a cross-sectional end view taken along line X-X in FIG. 25(A). In this embodiment, the disposition relationship among the regions and the structure in the sense of the mechanical point may be the same as the conventional ones described with reference to FIG. 27. To be specific, the vertical channel 5 provided between the source 7-1 and the drain 7-2 as rising from the substrate 1 is sandwiched between the pair of gate insulation films 6-1 and 6-2 in the direction orthogonal to the carrier-running direction within the channel, and the pair of gate insulation films 6-1 and 6-2 are provided thereon, respectively, with gate electrodes 3-1 and 3-2 that are paired, provided that the pair of gate electrodes 3-1 and 3-2 are electrically connected to each other at the portion 3c bridging over the insulation film 4 formed on the channel 5 and can therefore be regarded actually as a single member.

This embodiment differs from the preceding embodiments because the thicknesses of the pair of gate insulation films 6-1 and 6-2 are the same as each other. As a consequence of adopting the specific manner of the present invention, the permittivities ε1 and ε2 of the pair of gate insulation films 6-1 and 6-2 differ from each other (ε1≠ε2), or the work functions Φ1 and Φ2 of the pair of gate electrodes 3-1 and 3-2 differ from each other (Φ1≠Φ2), or the permittivities ε1 and ε2 of the pair of gate insulation films 6-1 and 6-2 differ from each other and the work functions Φ1 and Φ2 of the pair of gate electrodes 3-1 and 3-2 differ from each other.

For this reason, the aforementioned disadvantages in the conventional structure are eliminated or alleviated and, by adjusting the permittivities ε1 and ε2 of the gate insulation films during the device fabrication processes, a desirable threshold voltage within the range not increasing the subthreshold slope can be obtained even when the pair of gate electrodes 3-1 and 3-2 are electrically connected to each other and even when the respective potentials cannot be adjusted independently.

Similarly, by adjusting the work functions Φ1 and Φ2 of the pair of gate electrodes 3-1 and 3-2, a desirable threshold voltage within the range not increasing the subthreshold slope can be obtained.

By adjusting both the relation between the permittivities ε1 and ε2 and the relation between the work functions Φ1 and Φ2 complimentarily, of course, the threshold voltage can finely be adjusted.

The materials for the gate insulation films 6-1 and 6-2 having different permittivities ε1 and ε2 can be selected from the existing materials with a considerable degree of freedom and, due to the multilayer structure, the effective permittivity can be decided to a desirable value. Similarly, the materials for the gate electrodes 3-1 and 3-2 having the aforementioned relationship of the work functions can also be selected from the existing materials with a considerable degree of freedom and, as described earlier, they can be fabricated using the tilted ion implantation technique.

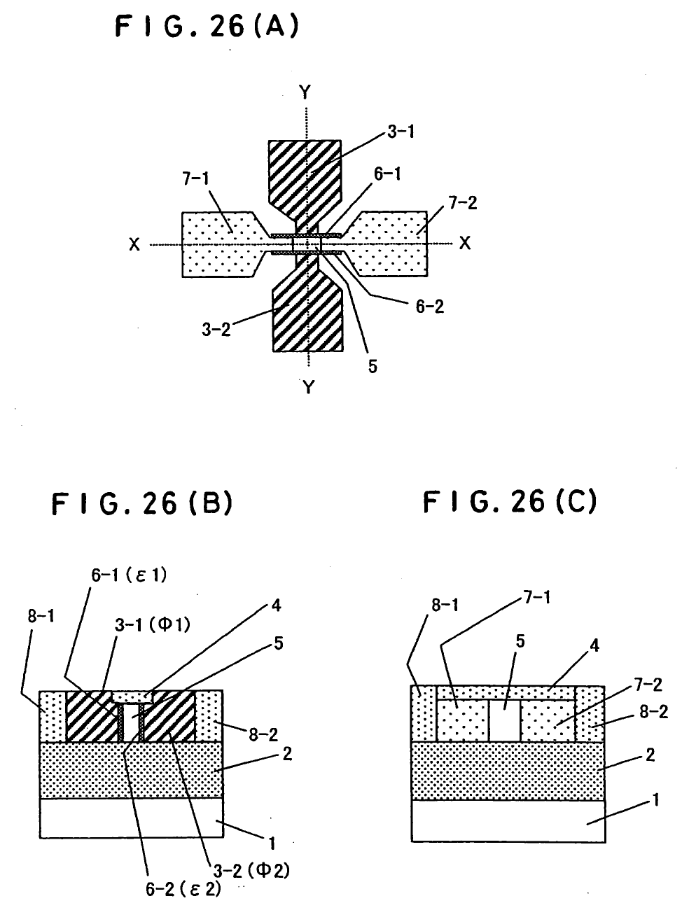

FIGS. 26(A) to 26(C) schematically show the configuration of the dual-gate field effect transistor according to a further embodiment of the present invention. This embodiment may have the same structure as the conventional one described with reference to FIG. 28. The vertical channel 5 provided between the source 7-1 and the drain 7-2 as rising from the substrate 1 is sandwiched between the pair of gate insulation films 6-1 and 6-2 in the direction orthogonal to the carrier-running direction in the vertical channel and, on the pair of gate insulation films 6-1 and 6-2, the gate electrode 3-1 and 3-2 which are paired are provided. The thicknesses of the pair of insulation films 6-1 and 6-2 are the same as each other.

Unlike the embodiment of FIG. 25, however, since the pair of gate electrodes 3-1 and 3-2 are electrically independent of each other and insulatively separated from each other, different potentials can be applied to the respective gate electrodes. In the case shown in the figure, the constituent elements including the channel 5 are formed on the buried oxide film 2 and the upper portion of the channel 5 is covered by the insulation film 4.

Also in this embodiment, in accordance with the gist of the present invention, the permittivities ε1 and ε2 of the pair of gate insulation films 6-1 and 6-2 are made different from each other, or the work functions Φ1 and Φ2 of the pair of gate electrodes 3-1 and 3-2 are set to differ from each other, or both the permittivities ε1 and ε2 of the pair of gate insulation films 6-1 and 6-2 and the work functions Φ1 and Φ2 of the pair of gate electrodes 3-1 and 3-2 are set to differ from each other.

For this reason, the drawbacks of the dual-gate field effect transistor having the conventional structure shown in FIG. 28 are eliminated and, therefore, it is possible to obtain a desired threshold voltage within the range not increasing the subthreshold slope. Furthermore, since the pair of gate electrodes 3-1 and 3-2 are electrically independent of each other, it is made possible to electrically control the threshold voltage dynamically also during the operation of the transistor.

Particularly, in the case of making the permittivities ε1 and ε2 different, by using the gate electrode 3-1 facing the gate insulation film 6-1 of relatively high permittivity ε1 as a drive electrode and applying an appropriate control potential to the gate electrode facing the gate insulation film 6-2 of a lower permittivity ε2, electrical control of the threshold voltage is dynamically enabled with a good controllability even during the device operation while preventing a steep increase in the subthreshold slope of the field effect transistor.

On the other hand, in the case of making the work functions Φ1 and Φ2 of the pair of gate electrodes 3-1 and 3-2 different, by using one of the gate electrodes as a drive electrode and applying a control potential to the other gate electrode, the threshold voltage can electrically be controlled while preventing a steep increase in the subthreshold slope of the field effect transistor and, if necessary, the threshold voltage can dynamically be controlled during the operation of the device.

Also, generally, in the method of applying a fixed bias to one of the pair of gate electrodes having a lower work function, it is possible to suddenly decrease the drain current depending on the applied bias to enable the drain current to be immediately shut off. In the method of applying a fixed bias to the other gate electrode having a higher work function, reversely, the current-voltage characteristic can be shifted in parallel depending on the applied bias to enable the threshold voltage to be controlled over a wide range.

### INDUSTRIAL APPLICABILITY

According to the present invention, since the thicknesses or permittivities of the pair of gate insulation films or the work functions of the pair of gate electrodes are made different from each other, it is possible to set the threshold voltage to a desirable value in the device fabrication processes even when the gate electrodes are electrically connected to each other. In the case of controlling the threshold voltage by channel doping with ion implantation, it is very difficult to overcome the impurity fluctuation with miniaturization of the channel size which results in the variation of the threshold voltage on a wafer. In the present invention, however, there is no such possibility and the problem of accretion in the subthreshold slope conventionally encountered can be solved.

Furthermore, in the specific manner of the present invention in which the pair of gate electrodes are made electrically independent of each other, the threshold voltage can electrically be controlled. By using as a drive electrode the gate electrode facing the thin gate insulation film and applying a control potential to the gate electrode facing the thick gate insulation film or by using as a drive electrode the gate electrode facing the gate insulation film of relatively high permittivity and applying an appropriate control potential to the gate electrode facing the gate insulation film of low permittivity, for example, the threshold voltage can become electrically controlled while preventing a steep increase in the subthreshold slope of the field effect transistor and, when necessary, the threshold voltage can dynamically be controlled during the operation of the device.

Also in the case of making the work functions of the pair of gate electrode different, in the method of applying a fixed bias to one of the pair of gate electrodes having a lower work function, it is possible to suddenly decrease the drain current depending on the applied bias to enable the drain current to be immediately shut off. In the method of applying a fixed bias to the other gate electrode having a higher work function, reversely, the current-voltage characteristic can be shifted in parallel depending on the applied bias to enable the threshold voltage to be controlled over a wide range.

Selection of two or all of means for making the thicknesses of the pair of gate insulation films different from each other means for making the permittivities thereof different from each other and means for making the work functions of the pair of gate electrodes different from each other makes it possible to control the threshold voltage more finely.

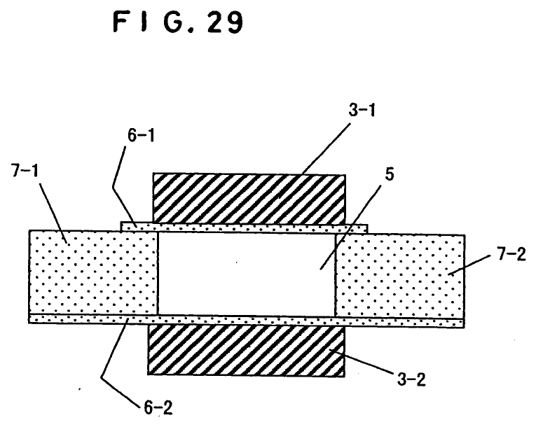

Structurally, since not a planar channel shown in FIG. 29, but a vertical channel is used, existing excellent fabrication techniques can effectively be utilized. For example, orientation-dependent wet etching technique can be used for the fabrication of vertical channels. As a result, plasma-induced damage is not introduced into channels unlike the case where dry etching has to be used, and the channel surface can be provided with the (111) plane in a self-limited manner and flattened on the order of an atomic layer surface. Therefore, a high-performance field effect transistor exhibiting a small decrease in mobility by the channel surface roughness scattering can be obtained.

Of course, since the source, drain and two gate electrodes can be disposed on the same main surface, the interconnection of the devices is made simple. Since, in the fabrication process, a channel is beforehand processed and two gate electrodes can be processed in the same process, the source and drain regions and two electrodes can be disposed in a self-aligning relationship. This means that deterioration of the device performance by fluctuation in parasitic capacitance and source and drain resistance can be prevented.

Making the vertical channel triangular in accordance with the specific manner of the present invention is effective for suppressing the short channel effect more.

The present invention can contribute to reduction in power consumption in a dual-gate field effect transistor structure. Since the present invention provides means for freely controlling the threshold voltage to a great extent, with respect to the operation of a dual-gate field effect transistor, for example, the threshold voltage is lowered when necessary to guarantee high-speed operation and, at the standby time, the threshold voltage is raised to lower the off current, thereby making it possible to suppress the power consumption during the non-operation. Therefore, even in a semiconductor integrated circuit comprising a plurality of the dual-gate transistors, not to mention a single unit of the device, there is no case where the performance thereof is lowered as compared with the conventional ones, and the power consumption can be suppressed to an optimum value while enhancing the performance of the device.

Incidentally, when the pair of gate electrodes are made independent of each other, i.e. when the dual-gate field effect transistor of the present invention is constituted as a four-terminal device including a source and a drain, there remains a probability of a new circuit function can be added in addition to the case where the potential applied to a pair of gate electrodes is adjusted only for the purpose of controlling the threshold voltage. At any rate, according to the present invention, the development up to date of silicon integrated circuits will not be retarded in future, and the capability of eliciting new functions of the silicon integrated circuits is very high. Thus, the present invention can grant a great favor to the semiconductor industry.

1. A dual-gate field effect transistor comprising a substrate, a source, a drain, a vertical channel provided between the source and the drain as rising from the substrate, a pair of gate insulation films sandwiching the channel from a direction orthogonal to a carrier-running direction in the channel and a pair of gate electrodes facing the channel, respectively, via the pair of gate insulation films, wherein the pair of insulation films have different thicknesses.

2. A dual-gate field effect transistor according to claim 1, wherein the pair of gate electrodes are electrically connected to each other.

3. A dual-gate field effect transistor according to claim 1, wherein the pair of gate electrodes are electrically independent of each other.

4. A dual-gate field effect transistor according to claim 1, wherein the pair of gate insulation films have different permittivities.

5. A dual-gate field effect transistor according to claim 1, wherein the pair of gate electrodes have different work functions.

6. A dual-gate field effect transistor according to claim 1, wherein the vertical channel has a triangle shape in cross section in the direction orthogonal to the carrier-running direction and wherein the pair of gate insulation films are in contact with slant faces that are opposed sides of the triangle, respectively.

7. A dual-gate field effect transistor comprising a substrate, a source, a drain, a vertical channel provided between the source and the drain as rising from the substrate, a pair of gate insulation films sandwiching the channel from a direction orthogonal to a carrier-running direction in the channel and a pair of gate electrodes facing the channel, respectively, via the pair of gate insulation films, wherein the pair of insulation films have different permittivities.

8. A dual-gate field effect transistor according to claim 7, wherein the pair of gate electrodes are electrically connected to each other.

9. A dual-gate field effect transistor according to claim 7, wherein the pair of gate electrodes are electrically independent of each other.

10. A dual-gate field effect transistor according to claim 7, wherein the pair of gate electrodes have different work functions.

11. A dual-gate field effect transistor according to claim 7, wherein the vertical channel has a triangle shape in cross section in the direction orthogonal to the carrier-running direction and wherein the pair of gate insulation films are in contact with slant faces that are opposed sides of the triangle, respectively.

12. A dual-gate field effect transistor comprising a substrate, a source, a drain, a vertical channel provided between the source and the drain as rising from the substrate, a pair of gate insulation films sandwiching the channel from a direction orthogonal to a carrier-running direction in the channel and a pair of gate electrodes facing the channel, respectively, via the pair of gate insulation films, wherein the pair of gate electrodes have different work functions.

13. A dual-gate field effect transistor according to claim 12, wherein the pair of gate electrodes are electrically connected to each other.

14. A dual-gate field effect transistor according to claim 12, wherein the pair of gate electrodes are electrically independent of each other.

15. A dual-gate field effect transistor according to claim 12, wherein the vertical channel has a triangle shape in cross section in the direction orthogonal to the carrier-running direction and wherein the pair of gate insulation films are in contact with slant faces that are opposed sides of the triangle, respectively.
